(19) United States
(12) Patent Application Publication
(10) Pub. No.: US 2015/0155137 A1
(43) Pub. Date: Jun. 4, 2015

(54) METHOD FOR MEASURING INCLINATION OF BEAM, DRAWING METHOD, DRAWING APPARATUS, AND METHOD OF MANUFACTURING OBJECT

(71) Applicant: CANON KABUSHIKI KAISHA, Tokyo (JP)

(72) Inventors: Koichi Sentoku, Tokyo (JP); Satoru Oishi, Utsunomiya-shi (JP); Hideki Ina, Tokyo (JP)

(21) Appl. No.: 14/553,555

(22) Filed: Nov. 25, 2014

(30) Foreign Application Priority Data
Nov. 29, 2013 (JP) 2013-247122

(51) Int. Cl. H01J 37/304; G01C 9/06; G03F 7/20; G01B 21/22

(52) U.S. Cl. CPC H01J 37/3045; G01B 21/22; G01C 9/06; G03F 7/2037; H01J 2237/30472; H01J 2237/063

(57) ABSTRACT

The present invention relates to a method for measuring inclination of a beam emitted to a substrate with respect to an optical-axis direction of an optical system for forming the beam. The method includes moving the substrate to a first height and a second height and turning the substrate about a rotational axis in the optical-axis direction. The method further includes acquiring a beam position with respect to the substrate situated at each of the first height and the second height both before and after the turning and determining the inclination of the beam based on the first height, the second height, and the beam positions.

### BACKGROUND OF THE INVENTION

1. Field of the Invention

The present invention relates to a method for measuring inclination of a beam, drawing method, drawing apparatus, and method of manufacturing an object.

2. Description of the Related Art

In a drawing apparatus for emitting a beam, such as an electron beam, to a specimen on a substrate and drawing a pattern, the beam before drawing may be inclined from an optical axis of an optical system for forming the beam. If the beam inclined with respect to the optical-axis direction is emitted, misalignment occurs between a position to be irradiated with the beam and a position actually irradiated with the beam. The magnitude of the misalignment varies with variations in height during the driving or minute flatness of the surface of the substrate. Thus a position where the pattern is actually drawn deviates from a position where the pattern is to be drawn.

Japanese Patent Laid-Open No. 2013-38297 describes a technique of measuring positional deviation of irradiation on mark boards by detecting reflected electrons in irradiating the plurality of mark boards having different heights with an electron beam and of reducing misalignment in drawing a pattern using the measurement result.

However, the technique described in Japanese Patent Laid-Open No. 2013-38297 is affected more easily by measurement accuracy for measuring an irradiation position of an electron beam as the positional deviation of irradiation on the mark boards is smaller, and the accuracy for correcting the misalignment in drawing the pattern may degrade.

### SUMMARY OF THE INVENTION

A method for measuring inclination of a beam according to the present invention is a method for measuring inclination of a beam emitted to a substrate with respect to an optical-axis direction of an optical system for forming the beam. The method includes moving the substrate to a first height and a second height, turning the substrate about a rotational axis in the optical-axis direction, acquiring a beam position with respect to the substrate situated at each of the first height and the second height both before and after the turning, and determining the inclination of the beam based on the first height, the second height, and the beam positions.

Further features of the present invention will become apparent from the following description of exemplary embodiments with reference to the attached drawings.

### BRIEF DESCRIPTION OF THE DRAWINGS

FIG. 1 illustrates a configuration of a drawing apparatus according to a first embodiment.

FIG. 2 illustrates a configuration of an overlay inspection apparatus.

FIG. 3 includes illustrations for describing a mark forming process in the first embodiment.

FIG. 4 is a flowchart for describing a method for measuring inclination of a beam according to the first embodiment.

FIG. 5 includes illustrations for describing a mark forming process in a second embodiment.

FIG. 6 is a flowchart for describing a method for measuring inclination of a beam according to the second embodiment.

### DESCRIPTION OF THE EMBODIMENTS

The present invention is directed to a method for measuring inclination of various kinds of beams, including an electron beam, ion beam, and laser beam. It is applicable to a drawing apparatus capable of forming a pattern latent image on a resist using the above-described beam.

### First Embodiment

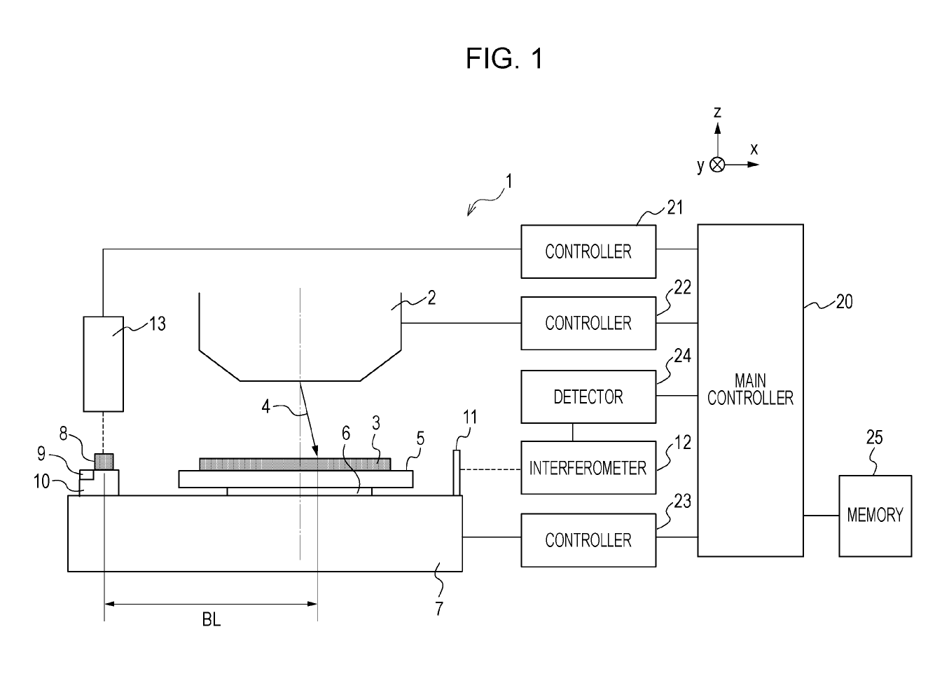

In a first embodiment, a drawing apparatus 1 for drawing a target pattern using a single electron beam is described as an example. FIG. 1 illustrates an apparatus configuration of the drawing apparatus 1 according to the present embodiment. An electronic optical system 2 includes a plurality of electron lenses (not illustrated) for forming the shape of an electron beam 4 emitted from an electron gun (not illustrated) toward a wafer 3 and a deflector (not illustrated) for deflecting the electron beam 4.

The wafer 3 (substrate) has a surface overlaid with a resist (not illustrated). The wafer 3 is held by an electrostatic force between the wafer 3 and a wafer chuck 5. The wafer chuck 5 is placed on a rotational stage 6 (rotational mechanism) capable of rotating the wafer 3 on the wafer chuck 5 at least 180 degrees. The rotational axis of the rotational stage 6 in the present embodiment is an optical axis of the electronic optical system 2 or is an axis that is spaced away from the optical axis by a predetermined distance and that is parallel to the optical axis (rotational axis in the optical-axis direction). That rotational axis is a straight line passing through the center of the wafer 3.

The rotational stage 6, on which the wafer chuck 5 holding the wafer 3 is placed, a mark board 10 including a fiducial mark 8 and a Faraday cup 9, and a mirror 11 are placed on a stage 7. The stage 7 can be moved in the x-, y-, and z-axis directions together with the wafer chuck 5, rotational stage 6, mark board 10, and mirror 11.

A base line BL indicates a relative distance between an optical axis of an alignment optical system 13 described below and the optical axis of the electronic optical system 2. In the present embodiment, if the electron beam 4 is inclined with respect to the optical axis, the base line BL indicates a relative distance between the optical axis of the alignment optical system 13 and an irradiation position of the electron beam 4.

The alignment optical system 13 is configured to measure a position of the fiducial mark 8. The Faraday cup 9 is configured to measure an irradiation position of the electron beam 4. A controller 21 described below is configured to determine the base line BL using the position of the fiducial mark 8, the irradiation position of the electron beam 4, and a known distance between the fiducial mark 8 and the Faraday cup 9.

An interferometer 12 is configured to split a laser beam emitted from a light source into measurement light and reference light and configured to cause the measurement light to be incident on the mirror 11 and the reference light to be incident on a reference mirror (not illustrated) disposed inside the interferometer 12. The light reflected from the mirror 11 and the light reflected from the reference mirror interfere with each other to form interference light. The position of the mirror 11, that is, the position of the stage 7 is detected by a detector 24 described below detecting the intensity of that interference light.

A rotation angle of the rotational stage 6 is measured by a rotary encoder (not illustrated). The measurement value is sent to a main controller 20 described below. The alignment optical system 13 is configured to detect the fiducial mark 8 or an alignment mark (not illustrated) formed on the wafer 3 in response to an instruction from the controller 21, which is described below.

The main controller 20 is connected to the controller 21 configured to control the alignment optical system 13, to a controller 22 configured to control the electronic optical system 2, and to a controller 23 configured to control driving of the rotational stage 6 and the stage 7. The main controller 20 is further connected to the detector 24 and a memory 25. The detector 24 is configured to detect the position of the stage 7 from the interference light intensity measured by the interferometer 12 and send the position of the stage 7 to the main controller 20.

The main controller 20 is configured to execute a program stored in the memory 25 using a central processing unit (CPU) retained inside the main controller 20. In executing the program, the main controller 20 controls the controllers 21, 22, and 23 and the detector 24. In addition, the main controller 20 is configured to store various measurement values in the memory 25 and perform calculation based on these measurement values.

The main controller 20 also functions as a correcting unit configured to correct misalignment in drawing the pattern using a result of beam inclination measurement described below. That is, the main controller 20 is configured to create drawing data that considers correction and provide the controller 22 and controller 23 with an instruction that considers correction.

The controller 22 is configured to adjust the position where the electron beam 4 is focused and the degree of deflection by controlling the electronic optical system 2. The controller 23 is configured to control the position of the stage 7 on the basis of position information on the stage 7 detected by the detector 24. The controllers 20, 21, 22, and 23 may be collectively configured on a single circuit substrate.

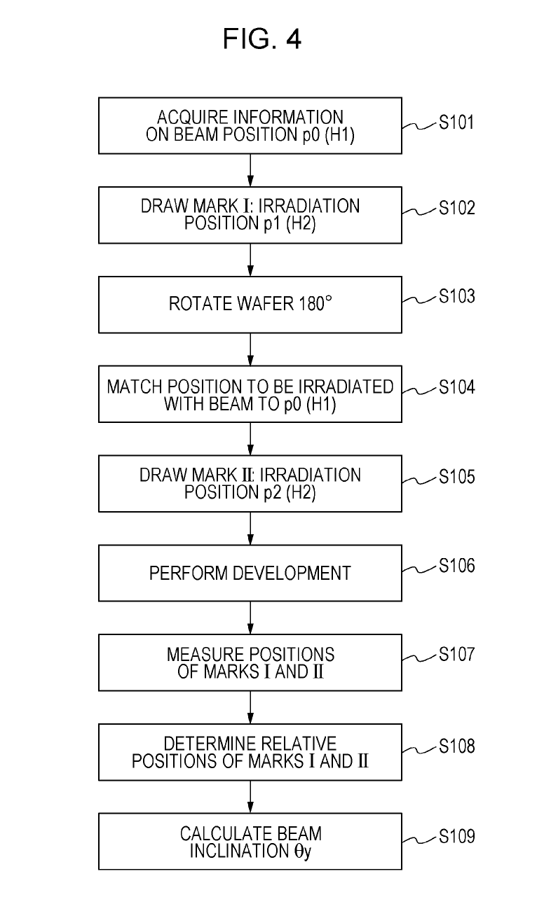

The memory 25 stores a program describing the process of S101 to S105 in a flowchart illustrated in FIG. 4 described below and data of a pattern to be drawn. Other data, such as coordinate values used in course of determining inclination of a beam and a determined value of the beam inclination (angle), is also made to be stored in the memory 25.

Members other than the controllers 20, 21, 22, and 23, detector 24, and memory 25 are arranged inside a vacuum chamber (not illustrated). The vacuum chamber is evacuated by a vacuum pump (not illustrated). The drawing apparatus 1 forms a pattern on the wafer 3 by controlling an irradiation position of the electron beam 4 and a relative position of the stage 7 while switching irradiation and non-irradiation with the electron beam 4 on the basis of the data of the pattern to be drawn stored in the memory 25.

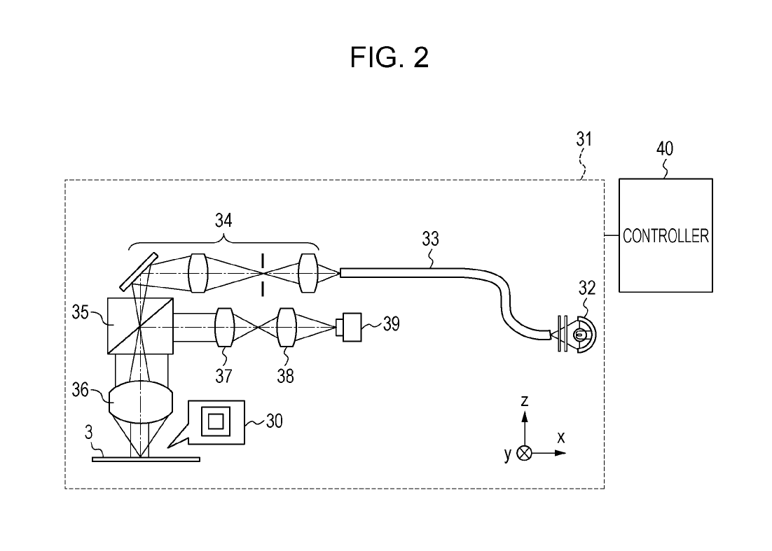

Next, a measurement apparatus 31 (position measuring instrument) is described with reference to FIG. 2. The measurement apparatus 31 is used in measuring inclination of a beam according to the present embodiment and is an overlay inspection apparatus for measuring a position of an overlay mark. The measurement apparatus 31 is an optical measurement apparatus used for detecting the position of a mark 30, which typically has a box-in-box shape, formed with drawing a pattern and inspecting overlay precision for a layer in which development is completed and its base layer. The mark 30 may have a bar-in-bar shape, which has no corners of rectangular marks.

FIG. 2 illustrates a configuration of the measurement apparatus 31. A light flux from a halogen lamp 32 passes through a fiber 33 and an illumination optical system 34. The light having passed through the illumination optical system 34 travels straight in a beam splitter 35, passes through an objective lens 36, and reaches the wafer 3.

The light reflected from the mark 30 on the wafer 3 passes through the objective lens 36 again and enters the beam splitter 35. The beam splitter 35 bends the optical path of the light. Then the light passes through a relay lens 37 and an erector 38 and forms an image of the mark 30 on an image pickup element surface of a charge-coupled device (CCD) camera 39. A controller 40 connected to the measurement apparatus 31 is configured to measure central coordinates of each of rectangular marks of the image of the mark 30 formed on the CCD camera 37 (hereinafter referred to as mark position) and obtain information on displacement of mark positions.

The information on displacement of mark positions indicates a relative distance between X components and a relative distance between Y components of the mark position of an inner mark and the mark position of an outer mark. It may indicate a relative distance between the mark position of the inner mark and the mark position of the outer mark obtained from the relative distance between the X components and the relative distance between the Y components.

Next, the method for measuring inclination of a beam according to the first embodiment is described. The inclination of the electron beam 4 is determined on the basis of two different heights (H1 and H2) and a beam position both before and after turning of the wafer 3 at each height (beam positions). The beam position indicates the irradiation position of the electron beam 4 when irradiation occurs, irrespective of irradiation or non-irradiation with the electron beam 4.

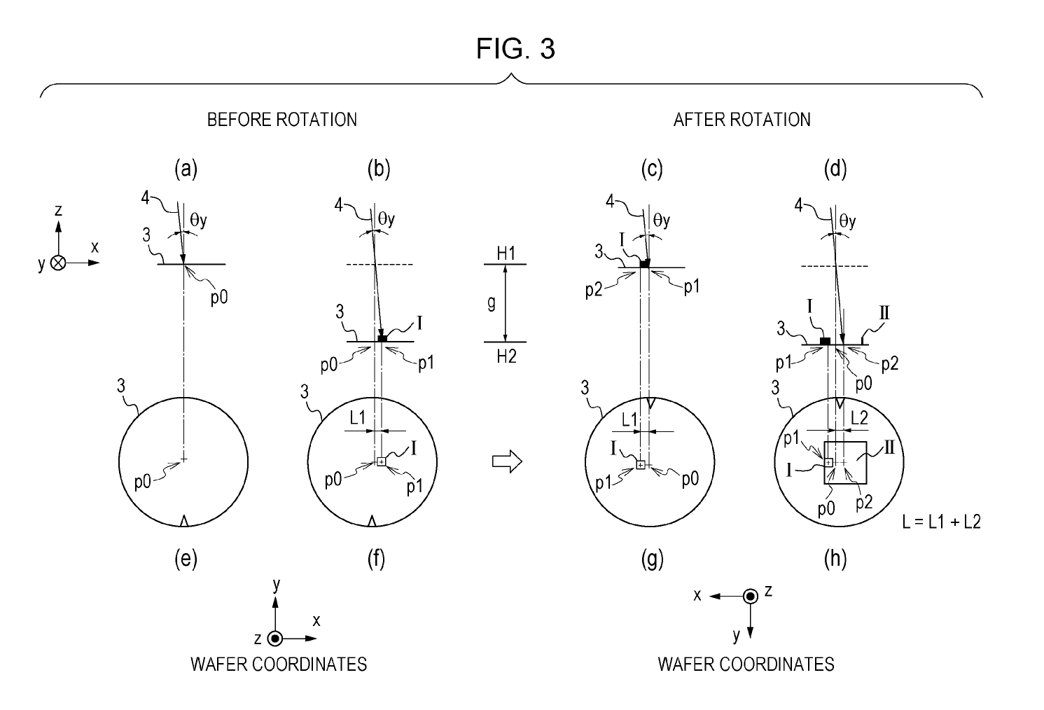

The present embodiment is a measurement method for a case in which there is no translational displacement on an XY plane in turning the wafer 3. A process of forming a mark to determine inclination of a beam is described below with reference to FIG. 3. A process from the process of forming the mark to determination of inclination of a beam is described with reference to the flowchart in FIG. 4. In the present embodiment, for the simplification of the description, it is assumed that, in a state where no deflector is used, the electron beam 4 is inclined angle θy from the optical axis of the electronic optical system 2 with respect to the y-axis being the rotational axis only in an XZ plane or a plane parallel to the XZ plane.

Here, the concept of wafer coordinates is adopted in the description of the beam measurement method. The wafer coordinates is a coordinate concept adopted to make the coordinate representation after rotation of the wafer 3 easier to understand. The axis of coordinates of the wafer coordinates rotates with rotation of the wafer 3. This enables a position on the wafer 3 before rotation and that after rotation to be represented as the same coordinates. The wafer coordinates are merely a concept, and the actual position of the wafer 3 is determined based on a result of measurement by the interferometer 12.

An example discussed here is a case in which the electron beam 4 is emitted to p (x, y), the wafer 3 is rotated 180 degrees about the center of the wafer 3, and then the electron beam 4 is emitted to the previously irradiated position again. In this example, the axis of coordinates determined by the interferometer 12 and that defined by the wafer coordinates coincide with each other. In this case, for the actual axis of coordinates determined by the interferometer 12, a position of second-time irradiation is to be expressed as “p′ (−x, −y) irradiated.” When the wafer coordinates are used, it can be expressed as “p (x, y) irradiated” after rotation. All the coordinates in the description below are represented using the wafer coordinates.

Parts (a) to (d) of FIG. 3 illustrate positional relationships between the electron beam 4 and the wafer 3 as seen from the y-axis direction. Parts (a) and (c) of FIG. 3 illustrate the state where the wafer 3 is situated at H1, which is a first height. Parts (b) and (d) of FIG. 3 illustrate the state where the wafer 3 is situated at H2, which is a second height spaced away from H1 by distance −g in the Z-axis direction. Parts (e) to (h) of FIG. 3 illustrate positional relationships between marks I and II described below formed on the wafer 3. Part (e) of FIG. 3 illustrates the state where the wafer 3 in the state illustrated in part (a) of FIG. 3 is seen from +Z direction. Similarly, part (b) of FIG. 3 corresponds to part (f) of FIG. 3, part (c) of FIG. 3 corresponds to part (g) of FIG. 3, and part (d) of FIG. 3 corresponds to part (h) of FIG. 3.

First, at S101, the controller 23 moves the stage 7 in the Z-axis direction such that the wafer 3 is situated at the height H1. Furthermore, the controller 23 moves the stage 7 in the x-axis direction and y-axis direction such that an irradiation position of the electron beam 4 is set at a predetermined position. At this time, the main controller 20 acquires irradiation position p0 (x0, y0) of the electron beam 4 and temporarily stores the coordinates of p0 in the memory 25. This state is illustrated in parts (a) and (e) of FIG. 3.

The value of the irradiation position p0 is acquired using the position of the stage 7 when the irradiation position of the electron beam 4 is identified by using the Faraday cup 9 to determine the base line BL and the position of the stage 7 when the irradiation position of the electron beam 4 is set at a position without irradiation with the electron beam 4. Next, at S102, the controller 23 moves the stage 7 by −g in the z-axis direction such that the wafer 3 is situated at the height H2. At this time, the controller 23 controls the position of the stage 7 on the basis of information on the position of the stage 7 detected by the detector 24 such that no movements occur in the x-axis direction and y-axis direction. In the description below, the same control is performed in movement in the z-axis direction on all occasions.

After adjusting the height of the wafer 3, the controller 23 draws a mark I having a rectangular shape whose center is an irradiation position p1 (x1, y1) on the wafer 3 situated at the height H2 using the electron beam 4 in the same state as that at the height H1. Because the electron beam 4 is inclined θy, the center position of the mark I is located away from p0 (x0, y0). This state is illustrated in parts (b) and (f) of FIG. 3.

At S103, the controller 23 turns the wafer 3 and the wafer chuck 5 about the rotational axis in the optical-axis direction by controlling the rotational stage 6. The turning here can be rotation of 180 degrees. In the case where a few rotational errors occur in the turning, that is, if the rotation deviates from 180 degrees, the effect of the rotational errors may be added to an inclination angle of the electron beam determined later. In the wafer coordinates, the coordinates p0 and p1 remain unchanged.

After that, at S104, the controller 23 moves the wafer 3 by +g in the z-axis direction such that the wafer 3 is situated at the height H1. Furthermore, the controller 23 matches the beam irradiation position to the position p0 (x0, y0) stored at S101 by moving the wafer 3 in the x-axis direction and y-axis direction, which are directions extending along the surface of the wafer 3 (in-plane directions). That is, actually, the irradiation position is matched to (−x0, −y0) on the axis of coordinates identified by the interferometer 12. At this time, the rotational driving at S103 and the height adjustment at S104 may be performed in either order. A state after the completion of the operation at S104 is illustrated in parts (c) and (g) of FIG. 3.

As S105, similar to S102, the controller 23 moves the wafer 3 from the height H1 to H2. The controller 22 draws a mark II having a rectangular shape whose center is an irradiation position p2 (x2, y2) of the electron beam 4 with respect to the substrate situated at the height H2. The mark II is to be larger than the mark I to have a box-in-box shape in combination of the mark I and mark II. Because the electron beam 4 is inclined θy, the mark II is located away from the mark I. This state is illustrated in parts (d) and (h) of FIG. 3. Because of the turning of the wafer 3, the controller 22 forms the mark II at a position displaced in the opposite direction to the mark I with respect to the coordinates of p0 (x0, y0).

At S106, the wafer 3 is taken out from the vacuum chamber, and the marks I and II drawn in the process of S101 to S105 are developed. The details of the process from S107 indicate measurement of the mark positions of the formed marks I and II and how the inclination θy of the electron beam 4 is determined based on the measurement result. At S107, the wafer 3 after the development is moved to below the objective lens 36 in the measurement apparatus 31, and the measurement apparatus 31 measures the mark positions of the marks I and II.

At S108, the controller 40 determines relative position of the marks I and II. In the present embodiment, which is an embodiment in which the inclination of the electron beam 4 has no y component, y0, y1, and y2 are the same. In contrast, because the electron beam 4 is inclined the angle θy and thus an x-component deviation occurs, the relative position of p1 (x1, y1) and p2 (x2, y2) is (x2−x1, 0).

At S109, the controller 40 determines the inclination θy of the electron beam 4. Because a relative distance L between both marks required for calculating the inclination θy is |x2−x1|, in the case where the angle θy is a minute angle, θy can be represented by Expression (1). “g” indicates a component of height. To calculate θy, a difference between the height H1 and H2 is used as “g”.

$${θ}_{y} = \frac{\vert L \vert / 2}{g} \qquad ( 1 )$$

L indicates the sum of the relative distance L1 between p0 (x0, y0) and p1 (x1, y1) and a relative distance L2 between p0 (x0, y0) and p2 (x2, y2). To determine the coordinates of p0, the technique according to the present embodiment using the wafer 3 having an alignment mark formed in advance may be employed.

As described above, the inclination θy of the electron beam 4 can be determined through the procedure illustrated in the flowchart in FIG. 4. The value of θy calculated here can be input into the drawing apparatus 1 before the drawing apparatus 1 draws a target pattern. In the case where the inclination is known, the drawing apparatus 1 can draw a pattern on the wafer 3 situated at a predetermined height while correcting misalignment in drawing the pattern occurring arising from the inclination of the electron beam 4. Alternatively, the controller 22 may calibrate the inclination of the electron beam 4 on the basis of the calculated inclination angle θy.

The calculation of the inclination θy of the electron beam 4 based on the coordinates p1 and p2 measured by the measurement apparatus 31 is to be performed by the controller 40. Alternatively, the result of measurement of the marks I and II by the measurement apparatus 31 may be sent from the controller 40 to the main controller 20, and the main controller 20 may calculate the inclination using Expression (1).

In the foregoing description, an example in which development is carried out only at the process of S106 is described. A process of developing only the mark I may be inserted after the mark I is drawn at S102. In that case, because once a negative resist has been developed, surrounding resists are removed, and thus a resist is to be applied again.

In the present embodiment, L, which is twice L/2 originally used to determine θy, can be obtained by the turning of the wafer 3 between drawing one mark and drawing the other mark. The controller 40 can achieve the advantage of accurately determining the inclination θy of the electron beam 4 using the acquired coordinates of p0 and the relative distance between the positions of the marks I and II drawn on the wafer 3.

For example, to determine the inclination of the electron beam 4 without turning the wafer 3, the controller 22 draws the marks while the wafer 3 is situated at the heights H1 and H2. The controller 40 determines the inclination of the electron beam 4 using displacement of the marks drawn at the heights. It is assumed that this displacement is 0.5 nm. When the present embodiment is used, because the displacement between the marks drawn at the height H2 both before and after the turning is approximately twice that in the above-described case, the inclination of the electron beam 4 is determined by substituting the value of L=1.0 nm into Expression (1).

In the case where reproducibility of measurement of the distance between the two marks by the measurement apparatus 31 is 0.1 nm, the difference between the displacement of the mark positions drawn at the same height both before and after the turning and the value of the reproducibility of measurement is larger, and the determination is less affected by measurement error originating from the measurement apparatus 31. Accordingly, the inclination of the electron beam 4 can be determined more accurately than before.

The accurate determination of the inclination θy of the electron beam 4 enables the main controller 20 to accurately determine misalignment in drawing on the XY plane arising from the inclination of the electron beam 4. The misalignment in drawing can be determined by substituting the inclination θy of the beam and the distance g from the electronic optical system 2 to each position of the surface of the wafer 3 into Expression (1) described above. The misalignment in drawing a pattern can be accurately reduced by drawing the pattern while correcting the misalignment in drawing at each position of the wafer 3 as an offset. As the distance g to each position of the surface of the wafer 3, a value measured by a focus measurement system (not illustrated) is used.

### Second Embodiment

Unlike the first embodiment, the second embodiment is an embodiment in which translational displacement on the XY plane of the wafer 3 occurring in driving for turning the wafer 3 can be compensated. The second embodiment differs from the first embodiment in that the controller 22 performs drawing in the state where the wafer 3 is situated at the height H1 and in that after the driving for turning the wafer 3, the alignment optical system 13 performs global alignment measurement and makes correction for reducing the effect of the translational displacement.

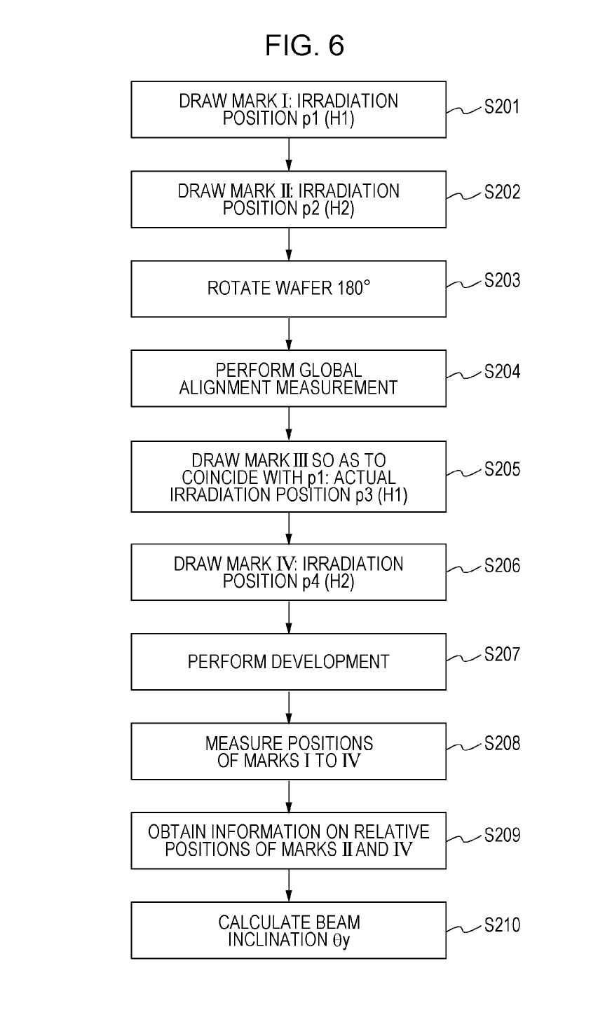

The second embodiment differs from the first embodiment in that a program describing the details of the process of S201 to S206 in the flowchart in FIG. 6 is stored in the memory 25. The main controller 20 provides the controllers 21, 22, and 23 with instructions to execute that program. In the present embodiment, the wafer 3 having a plurality of alignment marks (not illustrated) formed in advance is used. In the present embodiment, it is assumed that the electronic optical system 2 is inclined the angle θy from the optical axis of the electronic optical system 2 with respect to the y-axis being the rotational axis only in the XZ plane or a plane parallel to the XZ plane.

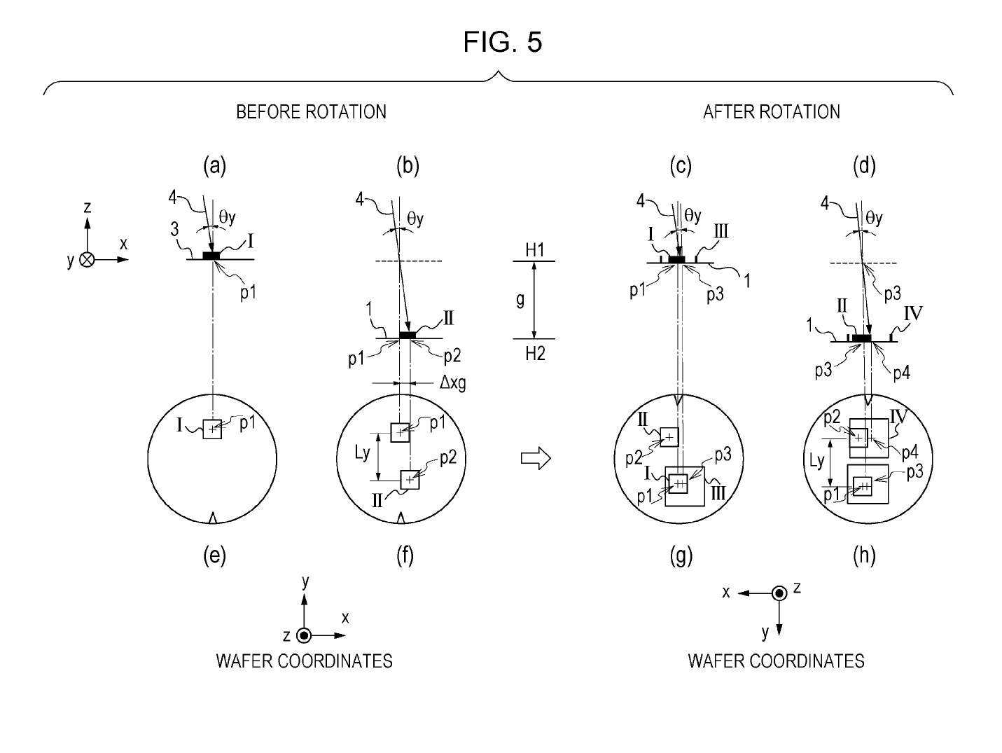

A mark forming process to determine inclination of a beam is described below with reference to FIG. 5. A process from the mark forming process to the determination of the beam inclination is described with reference to the flowchart in FIG. 6. Parts (a) to (h) of FIG. 5 illustrate positional relationships between the electron beam 4 and the marks formed on the wafer 3. The illustrating manner in FIG. 5 is substantially the same as that in FIG. 3 and is not described here.

First, at S201, the controller 23 moves the stage 7 such that the wafer 3 is situated at the height H1. The mark I is formed so as to have its center at the irradiation position p1 (x1, y1) of the electron beam 4 specified in a position on the wafer 3. The main controller 20 acquires the center position p1 (x1, y1) of the mark I and stores it in the memory 25. This state is illustrated in parts (a) and (e) of FIG. 5.

Next, at S202, the controller 23 moves the stage 7 by −g in the z-axis direction such that the wafer 3 is situated at the height H2. After the height adjustment, the wafer 3 is moved by Ly in the y-axis direction, and the mark II having a rectangular shape whose center is the irradiation position p2 (x2, y2) at the height H2 is drawn using the electron beam 4 in the same state as that at the height H1. The inclination θy of the electron beam 4 causes the mark II to be formed in a position spaced away from the mark I by Δxg in the x-axis direction. This state is illustrated in parts (b) and (f) of FIG. 5.

The movement of the wafer 3 by Ly in the y-axis direction is made to draw the next mark in a position spaced away from the mark I. Any value may be set as the amount Ly of the movement. The main controller 20 stores the amount Ly of the movement in the memory 25.

At S203, the wafer 3 is turned about the rotational axis in the optical-axis direction together with the wafer chuck 5 by the rotational stage 6. At this time, translational displacement arising from vibrations or the like in the driving for turning the wafer 3 may occur in the XY plane.

At S204, global alignment measurement is performed. That is, in response to an instruction from the controller 21, the alignment optical system 13 measures the positions of the plurality of alignment marks formed in advance on the wafer 3, performs statistical processing on the positions of the plurality of alignment marks, and thus corrects the translational displacement in the wafer 3. The measurement of the positions of the alignment marks enables correcting the displacement between the actual position of the wafer 3 and the position based on the measurement by the interferometer 12. With this, almost all of the translational displacement can be compensated. However, a certain degree of measurement error occurs in the measurement of the positions of the alignment marks.

After that, at S205, the controller 23 moves the wafer 3 by +g in the z-axis direction such that the wafer 3 is situated at the height H1. Furthermore, the controller 23 moves the stage 7 so as to allow the electron beam 4 to be emitted to the position of p1 (x1, y1) stored at S201. Then, a mark III is drawn so as to have its center at the irradiation position of the electron beam 4.

If no error occurs in the above-described correction based on the global alignment measurement, the coordinate position p3 (x3, y3) of the mark III coincides with p1 (x1, y1). However, in the case where minute error exists in the result of the correction by the global alignment measurement, the mark III is drawn in a position displaced from the mark I by correction error (Δx, Δy) based on the measurement of the positions of the alignment marks. This state is illustrated in parts (c) and (g) of FIG. 5.

The rotating operation at S203 and the height adjustment at S204 may be performed in either order, as in the first embodiment. At S206, similar to S202, the controller 23 drives the stage 7 such that the height of the wafer 3 changes from H1 to H2. After the height adjustment, the wafer 3 is moved by −Ly in the y-axis direction, and then a mark IV having a rectangular shape whose center is the irradiation position p4 (x4, y4) at the height H2 is drawn using the electron beam 4 in the same state as that at the height H1. The x coordinate of p4 is displaced from the x coordinate of p3 by −Δxg, and this displacement arises from the inclination of the electron beam 4.

At S207, the wafer 3 is taken out from the vacuum chamber, and the marks I to IV drawn in the process S201 to S206 are developed. The details of the process from S208 indicate measurement of the positions of the formed marks I to IV and how the inclination θy of the electron beam 4 is determined based on the measurement result. The respect in which the effect of correction error arising from the global alignment measurement is compensated is also described below.

At S208, the wafer 3 after the development is moved to below the objective lens 36 in the measurement apparatus 31, and the measurement apparatus 31 measures the positions of the marks I and III and the marks II and IV. The positions of the marks I to IV formed through the process of S201 to S206 can be described below. When the position of the mark I is p1 (x1, y1), the position of the mark II can be represented by Expression (2). The position of the mark III and the position of the mark IV can be represented by Expressions (3) and (4), respectively.

$$\begin{matrix}p 2 ( x 2 , y 2 ) = ( x 1 + Δ xg , y 1 - Ly ) & ( 2 ) \\ p 3 ( x 3 , y 3 ) = ( x 1 + Δ x , y 1 - Δ y ) & ( 3 ) \\ \begin{matrix}p 4 ( x 4 , y 4 ) = p 3 ( x 3 , y 3 ) + ( - Δ xg , - Ly ) \\ = ( x 1 + Δ x - Δ xg , y 1 + Δ y - L y )\end{matrix} & ( 4 )\end{matrix}$$

The displacements Δxg and −Δxg arise from the inclination of the electron beam 4. Ly is the amount of movement in drawing the marks II and IV. Because no inclination with respect to the x axis being the rotational axis occurs in the electron beam 4, no displacement other than Ly occurs in the y component. (Δx, Δy) arises from the correction error after the global alignment measurement.

At S209, positional deviation of the irradiation with the electron beam at the height H2 from the irradiation position of the electron beam at the height H1 is determined. To this end, the relative position L3 of the marks II and IV drawn at the height H2 are determined. The main controller 20 corrects the relative position L3 in consideration of the correction error (Δx, Δy), which is the relative position of the marks I and III (information on displacement of marks drawn on the substrate situated at the first height) and arises from the global alignment measurement, as an offset and determines the positional deviation of the irradiation at the height H2. (Δx, Δy) can be represented by Expression (5) using the coordinates p1 and p3. L3 can be represented by Expression (6) using Expressions (2) and (4).

(Δx,Δy)=(p3−p1)=(x1+Ax,y1+θy)−(x1,y1) (5)

L3=(p4−p2)=(Δx+2Δxg,Δy) (6)

The relative distance between p4 and p2 is determined to be 2Δxg by subtracting the correction error (Δx, Δy) in the global alignment measurement from Expression (5). Accordingly, the inclination θy of the electron beam 4 can be determined using Expression (7).

$$θ y = \frac{( L 3 - ( Δ x , Δ y ) ) / 2}{g} = \frac{2 Δ xg / 2}{g} = \frac{Δ xg}{g} \qquad ( 7 )$$

As in the first embodiment, the misalignment in drawing by the electron beam 4 occurring when the drawing apparatus 1 draws a pattern can be reduced by inputting the determined θy into the drawing apparatus 1.

The description of the method for measuring inclination of the electron beam 4 according to the second embodiment is completed. In the present embodiment, a mark is also formed at the height H1 both before and after the wafer 3 is turned. The controller 40 calculates L3 and (Δx, Δy) on the basis of the measured values of the marks I to IV measured by the measurement apparatus 31. Δxg and the inclination θy of the electron beam 4 can be determined by subtracting the correction error arising from the global alignment measurement as an offset value from L3.

There is the advantage in that, even when translational displacement occurs in the XY plane in the course of turning the wafer 3, formation of a mark at the height H1 both before and after the turning of the wafer 3 enables the translational displacement to be cancelled out and the inclination θy of the electron beam to be determined. Drawing in the state where the wafer 3 is situated at the height H2 both before and after the turning of the wafer 3 enables the displacement of the marks arising from the inclination of the electron beam 4 to be detected more largely than that when the wafer 3 is not turned. This can enhance the accuracy of measuring the inclination θy.

When a single alignment mark is formed on the wafer 3 in advance, the axis of coordinates may be simply corrected using measurement of the displacement of positions of the single alignment mark by the alignment optical system 13, instead of the global alignment measurement at S204.

When no alignment mark is formed on the wafer 3 in advance, the translational displacement in driving for turning the wafer 3 can be compensated without the global alignment measurement process (S204). In this case, there is displacement (Δx′, Δy′) larger than the correction error (Δx, Δy) after the global alignment measurement occurs. If the displacement is so large that the marks do not have a box-in-box shape, when a detection signal for use in reading the position is manually specified while the shape of the mark measured by the measurement apparatus 31 is observed, the measurement result can be corrected.

In the first and second embodiments, the wafer 3 is moved such that the beam position with respect to the substrate situated at the height H1 after turning is near (coincides with, in the first embodiment) the beam position with respect to the substrate situated at the height H1 acquired before the turning. By making them near each other as much as possible, the marks drawn on the wafer 3 at the height H2 both before and after the turning are near each other, and they are in the measurement range of the measurement apparatus 31.

### Third Embodiment

The first and second embodiments are described assuming the case in which only the inclination θy with respect to the y-axis being the rotational axis occurs in the electron beam 4. The present invention is also applicable to a case where, in addition to the inclination θy, inclination θx with respect to the x-axis being the rotational axis occurs. The case where the inclination of the electron beam 4 includes two components (θx, θy) is described using the first embodiment as an example. First, the relative distance |L| between p1 and p2 is determined by Expression (8) using the x component |x2−x1| and y component |y2−y1| of the relative coordinates of p1 and p2.

|L|=\sqrt{|x2−x1|²+|y2−y1|²} (8)

The inclination θ of the electron beam 4 is determined by substituting the relative distance |L| and the distance g between H1 and H2 into Expression (1) in which θy=θ. Subsequently, among electron beams having the inclination θ from the optical axis of the electronic optical system 2, the electron beam 4 inclined in a specific direction can be identified using the value acquired by dividing each of the x component and y component of the relative coordinates of p1 and p2 by two.

### Fourth Embodiment

The method for measuring inclination of a beam in the present invention is also applicable to a drawing apparatus for drawing a pattern on a single wafer 3 using a plurality of electron beams 4. The method for measuring the inclination of the electron beam 4 from the optical axis of the electronic optical system 2 for forming the electron beam 4 or from a straight line parallel to the optical axis is described using the second embodiment. Before the controller 23 turns the wafer 3, marks are simultaneously drawn at the heights H1 and H2 using the plurality of electron beams 4. After the controller 23 turns the wafer 3, the alignment optical system 13 performs global alignment measurement.

After the electron beams 4 are moved to the positions of the marks drawn at the height H1, marks are drawn again at the height H2. Development is performed on all the marks at the same time. The measurement apparatus 31 measures the displacement of the mark positions for each set of marks having a box-in-box shape drawn using the same electron beam 4.

In the present embodiment, the operation of turning the wafer 3 can increase the number of measurement points used in the measurement of inclination of a single electron beam, and this can lead to accurate measurement. In addition, because the process of simultaneously drawing marks using a plurality of electron beams and the process of measuring positions by the measurement apparatus 31 of the optical type are included, the inclinations of the plurality of electron beams can be measured with a short time.

### Fifth Embodiment

Depending on the type of the resist or the irradiation condition of the electron beam, positional measurement can be made using only an obtained mark latent image. In such a case, the development process at S106 in FIG. 4 or at S207 in FIG. 6 may be omitted. Thus the time required for the development process can be reduced.

In the case where the development process is omitted, because it is not necessary to take the wafer 3 out of the vacuum chamber, the alignment optical system 13 as a position measuring instrument as an alternative to the measurement apparatus 31 may measure the positions of marks. In this case, the time for taking the wafer 3 out, developing the drawn marks, and re-evacuating the vacuum chamber can be eliminated, and the time required for inspecting inclination of the electron beam 4 can be shortened. There is also an advantage in that the entire process in beam inclination measurement can be performed inside the drawing apparatus 1. Accordingly, a user who does not have the measurement apparatus 31 can correct misalignment in drawing arising from inclination of the beam.

In this case, the drawn marks may not necessarily have a box-in-box shape, and the marks may have any shape that allows the mark positions of the marks drawn at different timings to be identified.

Alternatively, instead of the wafer 3 to which a resist is applied, a substrate in which a change in color is easily visible, such as a glass plate to which a photochromic material is applied, may be used as a substrate for beam inclination measurement. Because the photochromic material changes in color when exposed to a beam having a specific wavelength, the positions of marks can be measured without the development process, and substantially the same advantage is obtainable.

### Other Embodiments

Lastly, embodiments other than the above-described first to fifth embodiments are described.

The irradiation positions of the electron beam 4 at the heights H1 and H2 may be determined by irradiation of drawn marks with the electron beam 4 and detection of reflected electrons from the surface of the marks or secondary electrons emitted from the marks. Alternatively, they may be determined by detection of reflected electrons or secondary electrons occurring by irradiating the resist with the electron beam 4, without drawing the marks.

Examples of the position measuring instrument for measuring the position of the beam by the above detection may include a detector in which a scintillator and an optical multiplier tube are combined and a Faraday cup.

To measure the drawn mark position, the technique of measuring it using the measurement apparatus 31 of the optical type is to be employed. This technique can measure it with a shorter time and more accurately, in comparison with the position measurement technique by detecting secondary electrons or the like, and can accurately correct misalignment in drawing.

In the present invention, because it is merely required that the positional deviation of the irradiation with the beam in states where the wafer 3 is situated at different heights can be determined, the height H1 and the height H2 can be interchangeable. If a mark is drawn at a height other than H1 and H2 both before and after the turning of the wafer 3 and information on the heights and the displacement of the marks is obtained, the process of calculating the inclination θ can also be omitted. This is because, if data is complemented using a result of misalignment in drawing at the heights, the misalignment in drawing at a predetermined height can be calculated and corrected.

The rotational stage 6 capable of rotating the wafer 3 by 180 degrees is described above as an example of a rotational mechanism for rotating the wafer 3. Other examples may also be used. For example, if the rotational stage 6 has a limitation on an angle at which it can rotate the wafer 3 at a time, the rotational stage 6 may be set such that the sum of angles of rotating operations repeated a predetermined number of times is 180 degrees. Alternatively, a technique of raising only the wafer 3 from the wafer chuck 5, rotating the wafer 3 180 degrees in the state where it is raised or using another device, and then placing the wafer 3 on the wafer chuck 5 again may also be used.

If there is concern about variations in base line BL, the base line BL may be measured whenever necessary and the base line amount may be corrected. The accuracy of alignment to the stored irradiation position can be enhanced by matching the position of the wafer 3 to the stored irradiation position of the electron beam (e.g., p0, p1) with reference to at least one alignment mark.

### [Method of Manufacturing Object]

A method of manufacturing an object, such as a device or reticle, in the present invention may include a process of drawing a pattern while correcting misalignment in drawing using the drawing method according to the present invention and a process of developing a substrate, such as a wafer or glass, on which the pattern is drawn. It may further include other known processes (e.g., oxidation, film formation, deposition, doping, flattening, resist removing, dicing, bonding and packaging).

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-247122, filed Nov. 29, 2013, which is hereby incorporated by reference herein in its entirety.

What is claimed is:

1. A method for measuring inclination of a beam emitted to a substrate with respect to an optical-axis direction of an optical system for forming the beam, the method comprising:
moving the substrate to a first height and a second height;
turning the substrate about a rotational axis in the optical-axis direction;
acquiring a beam position with respect to the substrate situated at each of the first height and the second height both before and after the turning; and
determining the inclination of the beam based on the first height, the second height, and the beam positions.

2. The method according to claim 1, wherein the inclination of the beam is determined based on the beam positions and a difference between the first height and the second height.

3. The method according to claim 1, further comprising:
moving the substrate in an in-plane direction of the substrate such that the beam position with respect to the substrate situated at the first height after the turning of the substrate is near the beam position with respect to the substrate situated at the first height acquired before the turning of the substrate.

4. The method according to claim 1, wherein the acquiring the beam position with respect to the substrate situated at the second height both before and after the turning includes:
drawing a mark at the beam position on the substrate situated at the second height both before and after the turning of the substrate, and
measuring a position of each of the marks drawn at the second height.

5. The method according to claim 4, wherein the acquiring the beam position with respect to the substrate situated at the first height both before and after the turning includes:
drawing the mark at the beam position on the substrate situated at the first height both before and after the turning, and
measuring a position of each of the marks drawn at the first height.

6. The method according to claim 4, wherein, in the acquiring the beam position with respect to the substrate situated at each of the first height and the second height both before and after the turning, the position of each of the marks drawn on the substrate situated at the second height both before and after the turning of the substrate is measured by an optical position measuring instrument.

7. The method according to claim 5, wherein, in the determining the inclination of the beam, information on displacement of the marks drawn on the substrate situated at the second height is acquired using information on displacement of the marks drawn on the substrate situated at the first height as an offset.

8. The method according to claim 5, wherein, in the acquiring the beam position with respect to the substrate situated at each of the first height and the second height both before and after the turning, the position of a set of the marks drawn on the substrate situated at the first height or the second height is measured using an overlay inspection apparatus.

9. The method according to claim 1, wherein the beam comprises a plurality of beams, and the inclination of each of the plurality of beams is measured using the single substrate.

10. A method for measuring inclination of a beam emitted to a substrate with respect to an optical-axis direction of an optical system for forming the beam, the method comprising:
drawing a mark on the substrate situated at a first height using the beam;
storing a position of the drawn mark;
turning the substrate about a rotational axis in the optical-axis direction, moving the substrate so as to allow the beam to be emitted to the stored position, and drawing a mark at the first height;
drawing a mark on the substrate situated at a second height both before and after the turning;
measuring the position of each of the drawn marks; and
determining the inclination of the beam based on a result in the measuring.

11. A method for measuring inclination of a beam emitted to a substrate with respect to an optical-axis direction of an optical system for forming the beam, the method comprising:
acquiring a beam position with respect to the substrate situated at a first height both before and after the substrate is turned about a rotational axis in the optical-axis direction;
acquiring a beam position with respect to the substrate situated at a second height different from the first height both before and after the substrate is turned about the rotational axis in the optical-axis direction; and
determining the inclination of the beam based on the first height, the second height, and the beam positions at each of the first and second heights.

12. A method of emitting a beam to a substrate and drawing a pattern, the method comprising:
moving the substrate to a first height and a second height;
turning the substrate about a rotational axis in an optical-axis direction;
acquiring a beam position with respect to the substrate situated at each of the first height and the second height both before and after the turning; and
correcting misalignment in drawing the pattern based on the first height, the second height, and the beam positions, the misalignment being caused by inclination of the beam.

13. The method according to claim 12, further comprising acquiring the beam position with respect to the substrate situated at a predetermined height,
wherein, in the correcting the misalignment in drawing the pattern, the predetermined height and the beam position with respect to the substrate situated at the predetermined height are used.

14. The method according to claim 12, wherein the acquiring the beam position with respect to the substrate both before and after the turning includes:
drawing a mark on the substrate situated at each of the first height and the second height both before and after the turning of the substrate, and
measuring a position of each of the marks drawn at each of the first and second heights.

15. The method according to claim 14, wherein the inclination of the beam is determined using a result of the measurement of the position of each of the marks, and the misalignment in drawing the pattern is corrected based on the inclination of the beam.

16. An apparatus for emitting a beam to a substrate and drawing a pattern, the apparatus comprising:
a rotational mechanism configured to turn the substrate about a rotational axis in an optical-axis direction of an optical system for forming the beam;
an instrument configured to measure a position of the beam on the substrate; and
a correcting unit configured to correct misalignment in drawing the pattern,
wherein the instrument is configured to acquire the beam position for the substrate situated at each of a first height and a second height different from the first height both before and after the substrate is turned using the rotational mechanism, and
the correcting unit is configured to correct the misalignment in drawing the pattern based on the first height, the second height, and the beam positions at each of the first and second heights.

17. The apparatus according to claim 16, wherein inclination of the beam with respect to the optical-axis direction is determined based on the first height, the second height, and the beam positions at each of the first height and the second height, and the misalignment in drawing the pattern caused by the inclination is corrected.

18. A method of manufacturing an object, the method comprising:
a drawing process of emitting a beam to a substrate and drawing a pattern; and
a developing process of developing the substrate with the pattern drawn in the drawing process,
wherein the drawing process includes:
moving the substrate to a first height and a second height,
turning the substrate about a rotational axis in an optical-axis direction,
acquiring a beam position with respect to the substrate situated at each of the first height and the second height both before and after the turning, and
correcting misalignment in drawing the pattern based on the first height, the second height, and the beam positions, the misalignment being caused by inclination of the beam.
